(19) United States
(12) Patent Application Publication
(10) Pub. No.: US 2022/0157687 A1
(43) Pub. Date: May 19, 2022

(54) CIRCUIT SUBSTRATE WITH HEAT DISSIPATION BLOCK AND PACKAGING STRUCTURE HAVING THE SAME

(71) Applicant: UNIMICRON TECHNOLOGY CORP., Taoyuan City (TW)

(72) Inventors: Chien-Chen LIN, Taoyuan City (TW); Ho-Shing LEE, Taoyuan City (TW)

(21) Appl. No.: 17/156,848

(22) Filed: Jan. 25, 2021

(30) Foreign Application Priority Data
Nov. 17, 2020 (TW) 109140125

(51) Int. Cl. H01L 23/367; H01L 23/538

(52) U.S. Cl. CPC H01L 23/367; H01L 23/5386

(57) ABSTRACT

A circuit substrate has an open substrate, a heat-dissipation block, multiple high thermal conductivity members, a first dielectric layer, a second dielectric layer, multiple first heat conductive members, and multiple second heat conductive members. The heat-dissipation block is disposed in the open substrate. Multiple high thermal conductivity members are mounted through the heat-dissipation block. The first dielectric layer exposes a part of one of two surfaces of the heat-dissipation block. The second dielectric layer exposes a part of the other surface of the heat-dissipation block. The first heat conductive members are in contact with the heat-dissipation block exposed from the first dielectric layer. The second heat conductive members are in contact with the part of the heat-dissipation block exposed from the second dielectric layer. Therefore, heat can be transferred quickly via the heat-dissipation block and the high thermal conductivity members to improve heat-dissipating capacity of the circuit substrate.

### BACKGROUND OF THE INVENTION

### 1. Field of the Invention

The present invention relates to a substrate structure, especially to a circuit substrate with a heat-dissipation block having high thermal conductivity.

### 2. Description of the Prior Arts

Generally speaking, a circuit substrate is used for mounting multiple electronic components such as chips, and forms an effective circuit. Electronic components generate heat when in operation. Therefore, heat-dissipation blocks are often mounted on the circuit substrate to transfer heat away from a circuit structure, thereby preventing performance loss of the electronic components due to heat.

However, as a total number of the electronic components, complexity of the circuit structure, and complexity of the circuit design all increase, the circuit substrate is prone to a state of high temperature, and it is difficult for the circuit substrate to dissipate large amount of heat quickly. As a result, improving heat-dissipating capacity is one of the important issues in the technical field of the invention.

To overcome the shortcomings, the present invention provides a circuit substrate with a heat-dissipation block and a packaging structure having the same to mitigate or obviate the aforementioned problems.

### SUMMARY OF THE INVENTION

The main objective of the present invention is to provide a circuit substrate with a heat-dissipation block and a packaging structure with the same. A heat-dissipation block is disposed in the circuit substrate, and at least one high thermal conductivity member is mounted through the heat-dissipation block to increase heat transfer efficiency to prevent the circuit substrate and a chip from being in a state of high temperature, thereby improving heat-dissipating capacity of the circuit substrate.

The circuit substrate has an open substrate, a heat-dissipation block, at least one high thermal conductivity member, a first dielectric layer, a second dielectric layer, at least one first heat conductive member, and at least one second heat conductive member. The open substrate is a plate and has a first surface, a second surface disposed opposite to the first surface, and an opening formed through the open substrate. The heat-dissipation block is disposed in the opening. The at least one high thermal conductivity member is disposed in the heat-dissipation block and mounted through the heat-dissipation block. A thermal conductivity of the at least one high thermal conductivity member is larger than a thermal conductivity of the heat-dissipation block. The first dielectric layer is disposed on the first surface and the heat-dissipation block. The first dielectric layer is connected to and in contact with the heat-dissipation block. A part of the heat-dissipation block is exposed from the first dielectric layer. The second dielectric layer is disposed on the second surface and the heat-dissipation block. The second dielectric layer is connected to and in contact with the heat-dissipation block. Another part of the heat-dissipation block is exposed from the second dielectric layer. The at least one first heat conductive member is disposed on the first dielectric layer. The at least one first heat conductive member is connected to and in contact with the part of the heat-dissipation block that is exposed from the first dielectric layer. The at least one second heat conductive member is disposed on the second dielectric layer. The at least one first heat conductive member is connected to and in contact with the part of the heat-dissipation block that is exposed from the second dielectric layer.

The packaging structure has a circuit substrate with a heat-dissipation block and a chip. The circuit substrate has an open substrate, a heat-dissipation block, at least one high thermal conductivity member, a first dielectric layer, a second dielectric layer, at least one first heat conductive member, and at least one second heat conductive member. The open substrate is a plate and has a first surface, a second surface disposed opposite to the first surface, and an opening formed through the open substrate. The heat-dissipation block is disposed in the opening. The at least one high thermal conductivity member is disposed in the heat-dissipation block and mounted through the heat-dissipation block. A thermal conductivity of the at least one high thermal conductivity member is larger than a thermal conductivity of the heat-dissipation block. The first dielectric layer is disposed on the first surface and the heat-dissipation block. A part of the heat-dissipation block is exposed out of the first dielectric layer. The second dielectric layer is disposed on the second surface and the heat-dissipation block. Another part of the heat-dissipation block is exposed out of the second dielectric layer. The at least one first heat conductive member is disposed on the first dielectric layer. The at least one first heat conductive member is connected to and in contact with the part of the heat-dissipation block that is exposed from the first dielectric layer. The at least one second heat conductive member is disposed on the second dielectric layer. The at least one first heat conductive member is connected to and in contact with the part of the heat-dissipation block that is exposed from the second dielectric layer. The chip is disposed on the at least one first heat conductive member. The chip is connected to and in contact with the at least one first heat conductive member.

In the present invention, heat can be transferred quickly via the heat-dissipation block and the at least one high thermal conductivity member to increase the heat transfer efficiency of the circuit substrate. As a result, the heat-dissipating capacity of the circuit substrate is improved.

Other objectives, advantages and novel features of the invention will become more apparent from the following detailed description when taken in conjunction with the accompanying drawings.

### BRIEF DESCRIPTION OF THE DRAWINGS

FIG. 1 is a schematic view of a circuit substrate with a heat-dissipation block in accordance with the present invention;

FIG. 2 is a sectional view of a heat-dissipation block of the circuit substrate in FIG. 1;

FIGS. 3A to 3G are schematic views showing a method for manufacturing an embodiment in accordance with the present invention; and

FIG. 4 is a schematic view of a packaging structure in accordance with the present invention.

### DETAILED DESCRIPTION OF THE PREFERRED EMBODIMENTS

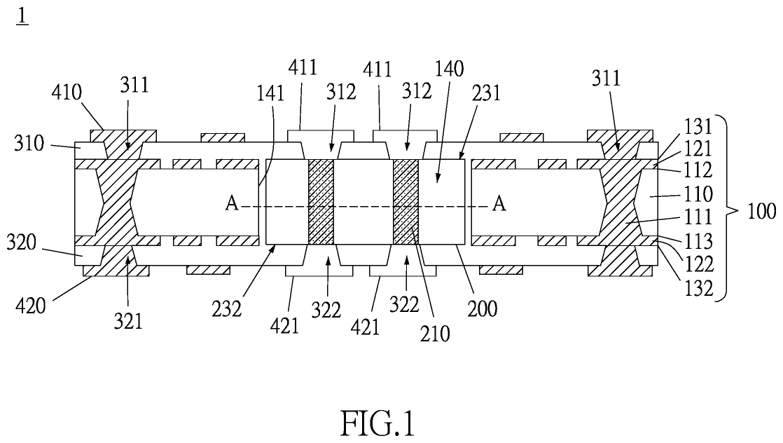

An embodiment of a circuit substrate with a heat-dissipation block in accordance with the present invention is shown in FIG. 1. The circuit substrate 1 comprises at least one open substrate 100, a heat-dissipation block 200, a first dielectric layer 310, a second dielectric layer 320, a first circuit layer 410, a second circuit layer 420, at least one first heat conductive member 411, and at least one second heat conductive member 421. The open substrate 100 is a plate and has a first surface 131 and a second surface 132 disposed opposite to the first surface 131. The first dielectric layer 310, the first circuit layer 410, and the at least one first heat conductive member 411 are disposed on the first surface 131. The second dielectric layer 320, the second circuit layer 420, and the at least one second heat conductive member 421 are disposed on the second surface 132.

The open substrate 100 has an opening 140, and the opening 140 is formed through the first surface 131 and the second surface 132 of the open substrate 100.

The heat-dissipation block 200 is disposed in the opening 140, and has a third surface 231 and a fourth surface 232 that are disposed opposite each other. At least one high thermal conductivity member 210 is disposed in the heat-dissipation block 200 and is mounted through the third surface 231 and the fourth surface 232 of the heat-dissipation block 200. A thermal conductivity of the at least one high thermal conductivity member 210 is larger than a thermal conductivity of the heat-dissipation block 200 such that heat can be transferred quickly by the at least one high thermal conductivity member 210, and heat can be transferred to an interior of the heat-dissipation block 200 in a lateral direction such that heat can be dissipated quickly by the bulk of the heat-dissipation block 200.

The first dielectric layer 310 is disposed on the first surface 131 and is disposed on the third surface 231 of the heat-dissipation block 200. The first dielectric layer 310 is connected to and in contact with the heat-dissipation block 200. The first dielectric layer 310 has at least one first electrically conductive via 311 and at least one first heat conduction hole 312. A part of the first surface 131 of the open substrate 100 is exposed from the at least one first electrically conductive via 311. A part of the third surface 231 of the heat-dissipation block 200 is exposed from the at least one first heat conduction hole 312.

The second dielectric layer 320 is disposed on the second surface 132 and is disposed on the fourth surface 232 of the heat-dissipation block 200. The second dielectric layer 320 is connected to and in contact with the heat-dissipation block 200. The second dielectric layer 320 has at least one second electrically conductive via 321 and at least one second heat conduction hole 322. A part of the second surface 132 of the open substrate 100 is exposed from the at least one second electrically conductive via 321. Another part of the fourth surface 232 of the heat-dissipation block 200 is exposed from the at least one second heat conduction hole 322.

Because the heat-dissipation block 200 is connected to and in contact with the first dielectric layer 310 and the second dielectric layer 320, the heat-dissipation block 200 can be fixed in the opening 140 to prevent unexpected displacement of the heat-dissipation block 200 in the subsequent processing of the circuit substrate 1.

The first circuit layer 410 is disposed on the first dielectric layer 310. The first circuit layer 410 is connected to and in contact with the first dielectric layer 310, and the first circuit layer 410 is electrically connected to the open substrate 100 via the first electrically conductive via 311.

The at least one first heat conductive member 411 is disposed on the first dielectric layer 310. The at least one first heat conductive member 411 is connected to and in contact with the first dielectric layer 310, and the at least one first heat conductive member 411 is connected to and in contact with the heat-dissipation block 200 via the at least one first heat conduction hole 312. Furthermore, the at least one first heat conductive member 411 is connected to and in contact with the third surface 231 via the at least one first heat conduction hole 312. As a result, heat can be transferred from the first heat conductive member 411 to the heat-dissipation block 200 via the first heat conduction hole 312.

The second circuit layer 420 is disposed on the second dielectric layer 320. The first circuit layer 410 is connected to and in contact with the second dielectric layer 320, and the first circuit layer 410 is electrically connected to the open substrate 100 via the second electrically conductive via 321.

The at least one second heat conductive member 421 is disposed on the second dielectric layer 320. The at least one first heat conductive member 411 is connected to and in contact with the second dielectric layer 320, and the at least one first heat conductive member 411 is connected to and in contact with the heat-dissipation block 200 via the at least one second heat conduction hole 322. Furthermore, the at least one first heat conductive member 411 is connected to and in contact with the fourth surface 232 via the at least one second heat conduction hole 322. As a result, heat transferred from the heat-dissipation block 200 via the second heat conduction hole 322 can be dissipated to external areas of the circuit substrate 1 by the second heat conductive member 421.

In the preferred embodiment, the at least one first heat conductive member 411 and the at least one second heat conductive member 421 are only used for transferring and dissipating heat; that is, the at least one first heat conductive member 411 and the at least one second heat conductive member 421 are neither adapted for electrical connection nor adapted for signal transmission.

In the preferred embodiment, the heat conducting material of the at least one first heat conductive member 411 and the at least one second heat conductive member 421 can be same as the electric conducting material of the first circuit layer 410 and the second circuit layer 420. In another preferred embodiment, said heat conducting material can be different from said electric conducting material.

Furthermore, the open substrate 100 has a core layer 110, a first core circuit layer 121, and a second core circuit layer 122. The core layer 110 has at least one electrically conductive via 111, a fifth surface 112, and a sixth surface 113 disposed opposite to the fifth surface 112. The first core circuit layer 121 is disposed on the fifth surface 112, and the first core circuit layer 121 is connected to and in contact with the core layer 110 and the first dielectric layer 310. The second core circuit layer 122 is disposed on the sixth surface 113, and the second core circuit layer 122 is connected to and in contact with the core layer 110 and the second dielectric layer 320. The first core circuit layer 121 and the second core circuit layer 122 are electrically connected to each other via the at least one electrically conductive via 111. The core layer 110 is located around the opening 140.

In a preferred embodiment, the third surface 231 of the heat-dissipation block 200 and the first surface 131 of the open substrate 100 are coplanar. The fourth surface 232 of the heat-dissipation block 200 and the second surface 132 of the open substrate 100 are coplanar. As a result, the first dielectric layer 310 can be formed evenly without undulation on the third surface 231 of the heat-dissipation block 200 and on the fourth surface 232 of the open substrate 100, and the second dielectric layer 320 can be formed evenly without undulation on the fourth surface 232 of the heat-dissipation block 200 and on the second surface 132 of the open substrate 100.

In a preferred embodiment, the first dielectric layer 310 is further disposed between an inner sidewall 141 of the opening 140 and the heat-dissipation block 200, and the first dielectric layer 310 is connected to and in contact with the second dielectric layer 320 to fix the heat-dissipation block 200 in the opening 140.

In a preferred embodiment, the at least one first heat conductive member 411 and the at least one second heat conductive member 421 are connected to and in contact with the at least one high thermal conductivity member 210. As a result, heat can be transferred to the heat-dissipation block 200 faster via the at least one high thermal conductivity member 210, and then heat can be dissipated away from the circuit substrate 1.

In a preferred embodiment, a material of the heat-dissipation block 200 is, but not limited to, copper.

In a preferred embodiment, a material of the at least one high thermal conductivity member 210 is, but not limited to, carbon.

As a result, heat can be transferred quickly to the interior of the heat-dissipation block 200 and the second heat conductive member 421 by the at least one high thermal conductivity member 210 such that heat can be dissipated to external areas the circuit substrate 1 by the bulk of the heat-dissipation block 200 and the second heat conductive member 421 simultaneously to improve heat-dissipating capacity of the circuit substrate 1.

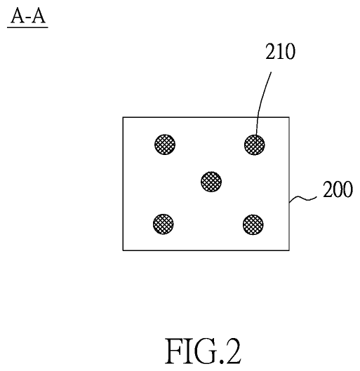

With reference to FIG. 2. FIG. 2 is a sectional view of the heat-dissipation block 200 cut across a cutting plane line A-A as shown in FIG. 1. In the preferred embodiment, multiple high thermal conductivity members 210 are distributed evenly in the heat-dissipation block 200. A number of the high thermal conductivity members 210 in FIG. 1 or FIG. 2 is illustrative only, and the number of the high thermal conductivity members 210 is not limited thereto.

In the preferred embodiment, the heat-dissipation block 200 is quadrilateral, but the shape of the heat-dissipation block 200 is not limited thereto. The shape of the heat-dissipation block 200 can be changed to circular or polygonal depending on the needs by a person having ordinary skill in the art.

A method for manufacturing an embodiment of the present invention is shown below with relevant figures using the circuit substrate 1 for example.

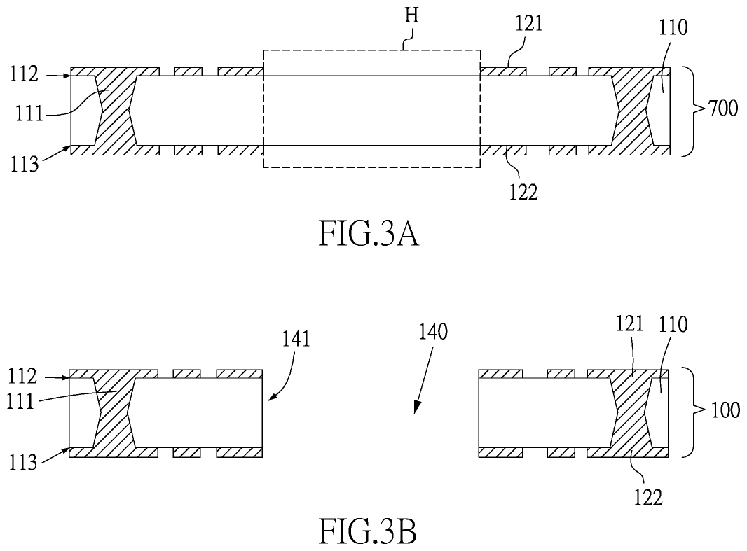

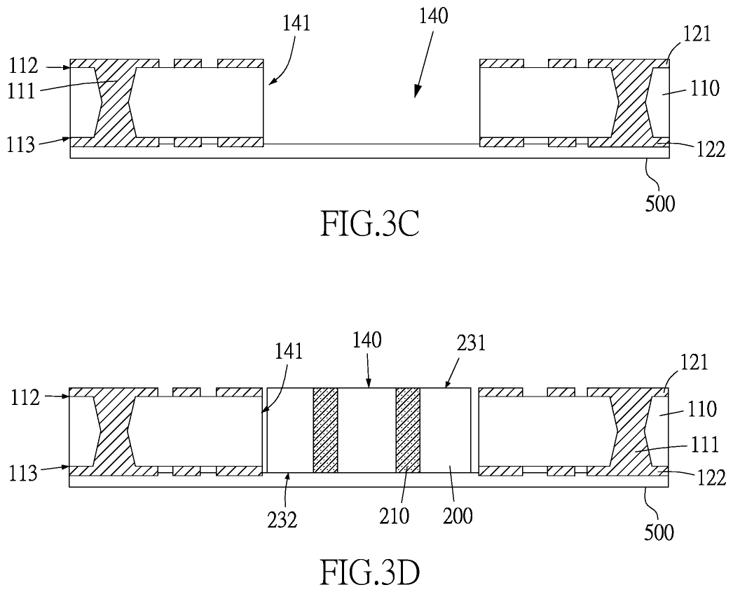

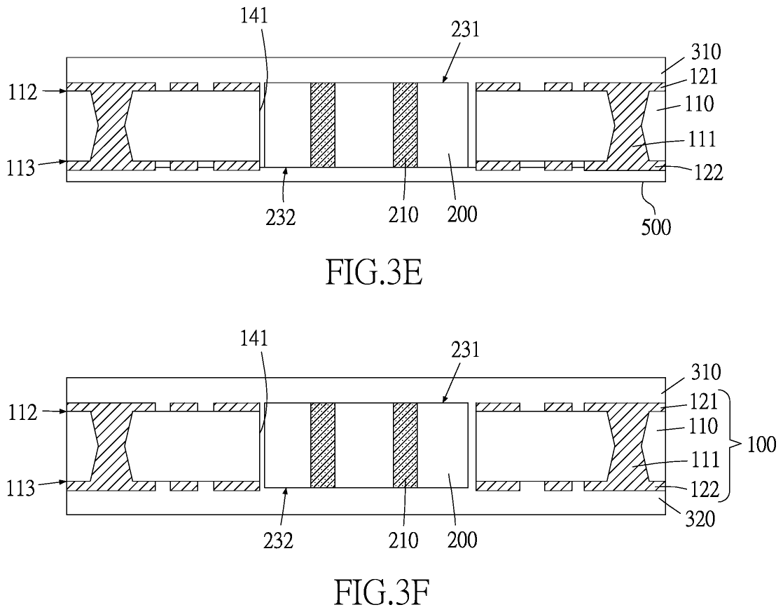

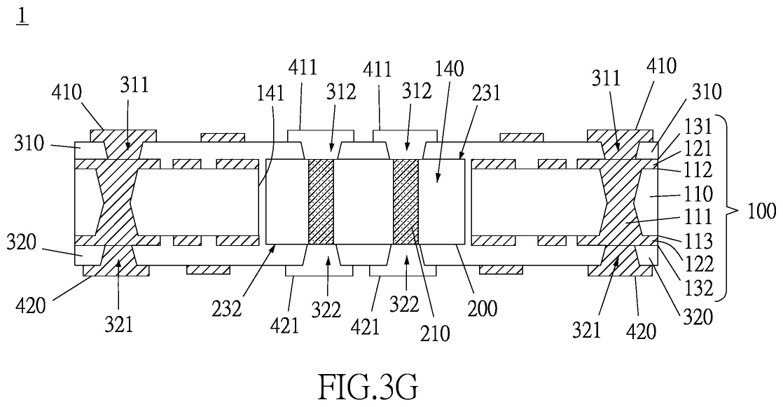

First, prepare a substrate 700 as shown in FIG. 3A. A first core circuit layer 121 is formed on a fifth surface 112 of a core layer 110, and a second core circuit layer 122 is formed on a sixth surface 113 of the core layer 110. An opening area H is defined in the core layer 110. The first core circuit layer 121 and the second core circuit layer 122 are not formed in the opening area H.

With reference to FIG. 3B, form an opening 140. Form the opening 140 in the opening area H of the core layer 110 to form an open substrate 100.

In a preferred embodiment, a manufacturing process to form the opening 140 may involve, but is not limited to, drilling, lasering, cutting, stamping, or a combination of the above.

With reference to FIG. 3C, form an adhesive layer 500. Apply an adhesive material on the second core circuit layer 122 such that the adhesive layer 500 provides mounting capability for the subsequent processing.

With reference to FIG. 3D, dispose a heat-dissipation block 200. The heat-dissipation block 200 is disposed in the opening 140 and mounted by the adhesive layer 500. At least one high thermal conductivity member 210 is disposed in the heat-dissipation block 200 and mounted through a third surface 231 and a fourth surface 232 of the heat-dissipation block 200. A thermal conductivity of the at least one high thermal conductivity member 210 is larger than a thermal conductivity of the heat-dissipation block 200 such that heat can be transferred to an interior of the heat-dissipation block 200 in the lateral direction such that heat can be dissipated quickly by the bulk of the heat-dissipation block 200.

With reference to FIG. 3E, form a first dielectric layer 310. Laminate the first dielectric layer 310 onto the first core circuit layer 121 and onto the third surface 231 of the heat-dissipation block 200 such that the heat-dissipation block 200 is connected to and in contact with the first dielectric layer 310.

In a preferred embodiment, the first dielectric layer 310 is further formed between an inner sidewall 141 of the opening 140 and the heat-dissipation block 200 to improve fixation of the heat-dissipation block 200 in the opening 140.

With reference to FIG. 3F, form a second dielectric layer 320. Remove the adhesive layer 500. Laminate the second dielectric layer 320 onto the second core circuit layer 122 and onto the fourth surface 232 of the heat-dissipation block 200 such that the heat-dissipation block 200 is connected to and in contact with the second dielectric layer 320. The heat-dissipation block 200 is fixed by the first dielectric layer 310 and the second dielectric layer 320.

In a preferred embodiment, the second dielectric layer 320 is connected to and in contact with the first dielectric layer 310 formed between the inner sidewall 141 of the opening 140 and the heat-dissipation block 200.

With reference to FIG. 3G, form a first circuit layer 410, at least one first heat conductive member 411, a second circuit layer 420, and at least one second heat conductive member 421. Form at least one first electrically conductive via 311 and at least one first heat conduction hole 312 in the first dielectric layer 310. Form at least one second electrically conductive via 321 and at least one second heat conduction hole 322 in the second dielectric layer 320. Then, form the first circuit layer 410 and the at least one first heat conductive member 411 on the first dielectric layer 310, and form the second circuit layer 420 and the at least one second heat conductive member 421 on the second dielectric layer 320 to complete forming the circuit substrate 1.

In a preferred embodiment, the first circuit layer 410 and the at least one first heat conductive member 411 can be formed in a same manufacturing process. The second circuit layer 420 and the at least one second heat conductive member 421 can be formed in a same manufacturing process.

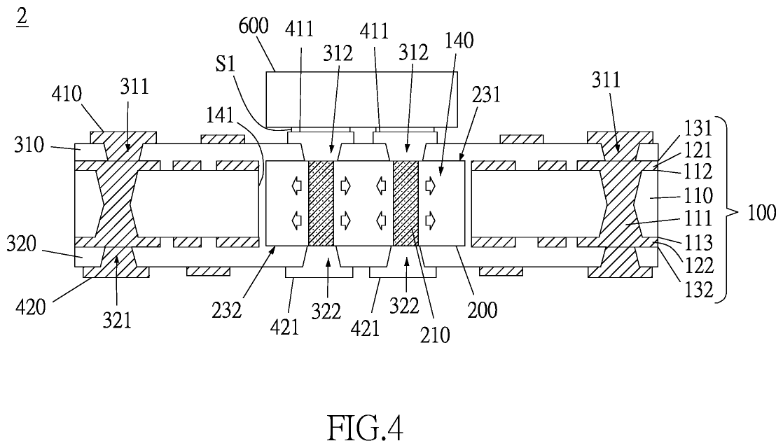

An embodiment of a packaging structure 2 in accordance with the present invention is shown in FIG. 4. The packaging structure 2 comprises a chip 600 disposed on the circuit substrate 1 as shown in FIG. 1 or FIGS. 3A to 3G. The chip 600 is connected to and in contact with the at least one first heat conductive member 411 of the circuit substrate 1 using soldering material Si such that heat generated by the chip 600 can be transferred to the heat-dissipation block 200 via the at least one first heat conductive member 411, and heat can be transferred quickly to an interior of the heat-dissipation block 200 through lateral direction (as shown in arrows in FIG. 4) such that heat can be dissipated to external areas of the circuit substrate 1 by the bulk of the heat-dissipation block 200 and the at least one second heat conductive member 421 to improve heat-dissipating capacity of the circuit substrate 1.

In summary, by disposing the at least one high thermal conductivity member 210 in the heat-dissipation block 200, heat can be transferred and dissipated to external areas of the circuit substrate 1 quickly to prevent the circuit substrate 1 from being in a state of high temperature, thereby improving the heat-dissipating capacity of the circuit substrate 1.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A circuit substrate comprising:
an open substrate being a plate and having:
a first surface;
a second surface disposed opposite to the first surface;
an opening formed through the open substrate;
a heat-dissipation block disposed in the opening;
at least one high thermal conductivity member disposed in the heat-dissipation block and mounted through the heat-dissipation block; a thermal conductivity of the at least one high thermal conductivity member being larger than a thermal conductivity of the heat-dissipation block;
a first dielectric layer disposed on the first surface and the heat-dissipation block; the first dielectric layer connected to and in contact with the heat-dissipation block; a part of the heat-dissipation block exposed out of the first dielectric layer;
a second dielectric layer disposed on the second surface and the heat-dissipation block; the second dielectric layer connected to and in contact with the heat-dissipation block; another part of the heat-dissipation block exposed out of the second dielectric layer;
at least one first heat conductive member disposed on the first dielectric layer; the at least one first heat conductive member connected to and in contact with the part of the heat-dissipation block that is exposed from the first dielectric layer; and
at least one second heat conductive member disposed on the second dielectric layer; the at least one first heat conductive member connected to and in contact with said another part of the heat-dissipation block that is exposed from the second dielectric layer.

2. The circuit substrate as claimed in claim 1, wherein the at least one first heat conductive member and the at least one second heat conductive member are connected to and in contact with the at least one high thermal conductivity member.

3. The circuit substrate as claimed in claim 1, wherein the first dielectric layer is disposed between an inner sidewall of the opening and the heat-dissipation block.

4. The circuit substrate as claimed in claim 2, wherein the first dielectric layer is disposed between an inner sidewall of the opening and the heat-dissipation block.

5. The circuit substrate as claimed in claim 3, wherein the first dielectric layer and the second dielectric layer are connected to and in contact with each other.

6. The circuit substrate as claimed in claim 4, wherein the first dielectric layer and the second dielectric layer are connected to and in contact with each other.

7. The circuit substrate as claimed in claim 1, wherein a material of the at least one high thermal conductivity member is carbon.

8. The circuit substrate as claimed in claim 6, wherein a material of the at least one high thermal conductivity member is carbon.

9. A packaging structure comprising:
an open substrate being a plate and having
a first surface;
a second surface disposed opposite to the first surface;
an opening formed through the open substrate;
a heat-dissipation block disposed in the opening;
at least one high thermal conductivity member mounted through the heat-dissipation block; a thermal conductivity of the at least one high thermal conductivity member being larger than a thermal conductivity of the heat-dissipation block;
a first dielectric layer disposed on the first surface and the heat-dissipation block; a part of the heat-dissipation block exposed out of the first dielectric layer;
a second dielectric layer disposed on the second surface and the heat-dissipation block; another part of the heat-dissipation block exposed out of the second dielectric layer;
at least one first heat conductive member disposed on the first dielectric layer; the at least one first heat conductive member connected to and in contact with the part of the heat-dissipation block that is exposed from the first dielectric layer;
at least one second heat conductive member disposed on the second dielectric layer; the at least one first heat conductive member connected to and in contact with said another part of the heat-dissipation block that is exposed from the second dielectric layer; and
a chip disposed on the at least one first heat conductive member; the chip connected to and in contact with the at least one first heat conductive member.

10. The packaging structure as claimed in claim 9, wherein the at least one first heat conductive member and the at least one second heat conductive member are connected to and in contact with the at least one high thermal conductivity member.

11. The packaging structure as claimed in claim 9, wherein the first dielectric layer is disposed between an inner sidewall of the opening and the heat-dissipation block.

12. The packaging structure as claimed in claim 10, wherein the first dielectric layer is disposed between an inner sidewall of the opening and the heat-dissipation block.

13. The packaging structure as claimed in claim 11, wherein the first dielectric layer and the second dielectric layer are connected to and in contact with each other.

14. The packaging structure as claimed in claim 12, wherein the first dielectric layer and the second dielectric layer are connected to and in contact with each other.

15. The packaging structure as claimed in claim 9, wherein a material of the at least one high thermal conductivity member is carbon.

16. The packaging structure as claimed in claim 14, wherein a material of the at least one high thermal conductivity member is carbon.
